(19) United States
(12) Patent Application Publication
(10) Pub. No.: US 2021/0028859 A1
(43) Pub. Date: Jan. 28, 2021

(54) FIBER-OPTICS COMMUNICATION COMPONENT TEST DEVICE

(71) Applicant: INSTRONTEK CO., LTD, Taoyuan City (TW)

(72) Inventor: CHI-MIN TING, Taoyuan City (TW)

(21) Appl. No.: 16/807,210

(22) Filed: Mar. 3, 2020

(30) Foreign Application Priority Data
Jul. 24, 2019 (TW) 108126219

(51) Int. Cl. H04B 10/077; H04B 10/25

(52) U.S. Cl. CPC H04B 10/0775; H04B 10/2504

(57) ABSTRACT

A fiber-optics communication component test device is provided, which includes a daughterboard, a motherboard and a connector. The daughterboard includes a controller and the controller generates a digital waveform signal (or bit signal). The motherboard includes a test area and a fiber-optics communication component is disposed in the test area. The connector is disposed on the motherboard and the daughterboard is detachably connected to the connector. The fiber-optics communication component receives the digital waveform signal via the connector to generate a light signal. The light signal is processed by a signal processing system to generate an input signal. The controller receives the input signal and generates a test result, including bit error rate, voltage amplitude and electric signal eye pattern, according to the input signal.

### CROSS REFERENCE TO RELATED APPLICATION

All related applications are incorporated by reference. The present application is based on, and claims priority from, Taiwan Application Serial Number 108126219, filed on Jul. 24, 2019, the disclosure of which is hereby incorporated by reference herein in its entirety.

### TECHNICAL FIELD

The technical field relates to a test device, in particular to a fiber-optics communication component test device.

### BACKGROUND

With advance of technology, optical communication is becoming more prevalent. Currently, optical communication has been applied to various different fields, such as telecommunications, various industries, medical care, education and national defense, etc. The communication of an optical communication network is realized by using light to carry information, so the optical communication network needs a lot of fiber-optics communication components. So as to make sure that the fiber-optics communication components can achieve high performance, these fiber-optics communication components should be carefully tested.

So as to assess the performance of the fiber-optics communication components, a tester usually needs to test the bit error rate (BER) via a BER tester. The tester should put a fiber-optics communication component (e.g. a transmitter or a TOSA) on a test board, and connect the high-frequency connectors of the test board to the high-frequency connectors of the BER tester via several high-frequency cables. Then, the tester can perform single-channel test or multi-channel test for the fiber-optics communication component. When the tester performs multi-channel test for the fiber-optics communication component, the quantity of the high-frequency connectors and high-frequency cables increases with the quantity of the test channels, which significantly increases the cost of multi-channel test because the high-frequency connectors and high-frequency cables are very expensive.

Besides, the BER tester has only downward compatibility, but has no upward compatibility. For example, a 4-channel BER tester cannot be applied to 8-channel test. Thus, if the tester needs to perform 8-channel test, the tester needs an 8-channel BER tester; meanwhile, the tester should also substitute an 8-channel test board for the 4-channel test board, which further increases the cost of multi-channel test.

In addition, if the tester needs to test the fiber-optics communication component under different temperatures, the tester should change the test temperature via a thermal streamer. The thermal streamer can change the temperature gradient in a short time; however, the cost of the thermal streamer is very high, which also increases the test cost of fiber-optics communication components.

Therefore, it has become an important issue to provide an optics communication component test device in order to solve the above problems of currently available fiber-optics communication component test devices.

### SUMMARY

Therefore, it is a primary objectives of the disclosure to provide a fiber-optics communication component test device so as to solve the above problems of currently available fiber-optics communication component test devices.

To achieve the foregoing objective, the disclosure provides a fiber-optics communication component test device, which may include a daughterboard, a motherboard and a connector. The daughterboard may include a controller and the controller may generate a digital waveform signal (or bit signal). The motherboard may include a test area and a fiber-optics communication component may be disposed in the test area. The connector may be disposed on the motherboard and the daughterboard may be detachably connected to the connector. The fiber-optics communication component may receive the digital waveform signal via the connector to generate a light signal. The light signal may be processed by a signal processing system to generate an input signal. The controller may receive the input signal and generate a test result.

In an embodiment of the disclosure, the daughterboard may include a terminal and the connector may include a socket; the terminal of the daughterboard may be inserted into the socket, whereby the daughterboard can be detachably connected to the connector.

In an embodiment of the disclosure, the fiber-optics communication component test device may further include a thermoelectric cooling chip module disposed in the test area, wherein the thermoelectric cooling chip module may include an accommodating space and the fiber-optics communication component may be disposed in the accommodating space.

In an embodiment of the disclosure, the thermoelectric cooling chip module may include a casing and a thermoelectric cooling chip; the thermoelectric cooling chip may be disposed in the casing and the test space inside the casing may be filled with inert gas.

In an embodiment of the disclosure, the daughterboard may be a single-channel test board or a multi-channel test board.

In an embodiment of the disclosure, the controller may further include a pseudo randomness binary sequence pattern generator and a bit error rate tester.

In an embodiment of the disclosure, the digital waveform signal may be a sinusoidal wave signal, a square wave signal or a pseudo randomness binary sequence signal.

In an embodiment of the disclosure, the test result may include a bit error rate, a voltage amplitude and an eye pattern.

In an embodiment of the disclosure, the fiber-optics communication component may be a laser diode, a laser package element, a light receiving package element, a light transmitting package element, a photodiode or a transceiver.

In an embodiment of the disclosure, the fiber-optics communication component test device may further include a housing and at least one portion of the test area may be exposed from the housing.

As described above, the fiber-optics communication component test device in accordance with the embodiments of the disclosures has the following advantages:

(1) In one embodiment of the disclosure, the fiber-optics communication component test device integrates a daughterboard, a motherboard and a connector with each other, so the digital waveform signal generated by the controller of the motherboard can be directly transmitted to the fiber-optics communication component disposed on the test area of the motherboard via the connector for the fiber-optics communication component to transmit a light signal. Then, the controller can directly receive the input signal generated by a signal processing system after the signal processing system processes the light signal. Therefore, the fiber-optics communication component test device does not need additional high-frequency connectors, high-frequency cables and test board, which can significantly reduce the cost of multi-channel test.

(2) In one embodiment of the disclosure, the fiber-optics communication component test device integrates the daughterboard, the motherboard and the connector with each other, so the daughterboard can be detachably connected to the connector. Thus, the tester can replace the daughterboard by another daughterboard according to different test requirements, which can further decrease the cost of multi-channel test.

(3) In one embodiment of the disclosure, the fiber-optics communication component test device includes a thermoelectric cooling chip module, which not only can swiftly change the temperature gradient, but also is of low cost, which can effectively the test cost of fiber-optics communication components.

(4) In one embodiment of the disclosure, the thermoelectric cooling chip module of the fiber-optics communication component test device includes a casing and a thermoelectric cooling chip disposed inside the casing, and the test space of the casing is filled with inert gas, which can effectively prevent from generating condensed water, so the test result can be more correct.

(5) In one embodiment of the disclosure, the structure of the fiber-optics communication component test device is simple, so can achieve the desire technical effects under this premise of reducing cost, which can significantly increase the commercial value of the test device.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The disclosure will become more fully understood from the detailed description given herein below and the accompanying drawings which are given by way of illustration only, and thus are not limitative of the disclosure and wherein:

FIG. 1 is a perspective view (without housing) of a fiber-optics communication component test device of a first embodiment in accordance with the disclosure.

FIG. 2 is a side view (without housing) of the fiber-optics communication component test device of the first embodiment in accordance with the disclosure.

FIG. 3 is a perspective view (with housing) of the fiber-optics communication component test device of the first embodiment in accordance with the disclosure.

FIG. 4 is a perspective view (without housing) of a fiber-optics communication component test device of a second embodiment in accordance with the disclosure.

FIG. 5 is a side view (without housing) of the fiber-optics communication component test device of the second embodiment in accordance with the disclosure.

FIG. 6 is a perspective view (with housing) of the fiber-optics communication component test device of the second embodiment in accordance with the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

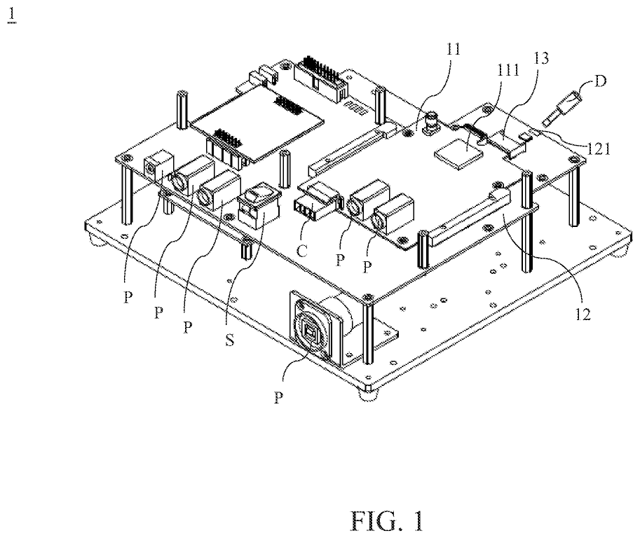

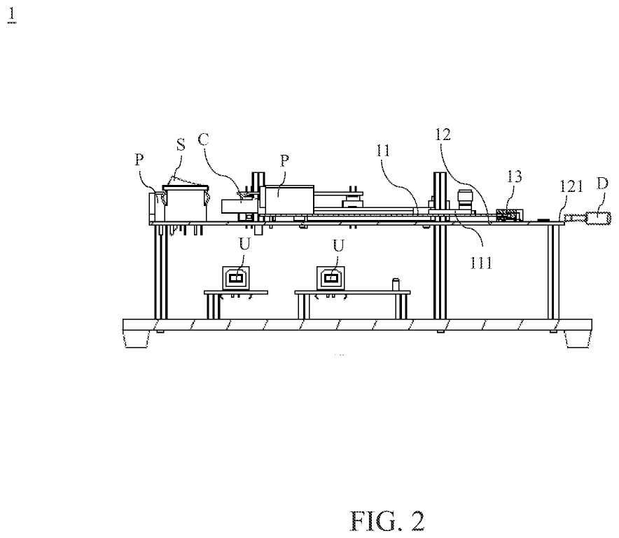

FIG. 1 and FIG. 2 are a perspective view (without housing) and a side view (without housing) of a fiber-optics communication component test device of a first embodiment in accordance with the disclosure respectively. As shown in FIG. 1 and FIG. 2, the fiber-optics communication component test device 1 includes a daughterboard 11, a motherboard 12 and a connector 13.

The daughterboard 11 includes a controller 111 and the controller 111 generates a digital waveform signal (or bit signal). In one embodiment, the daughterboard 11 may be a single-channel test board or a multi-channel test board. In one embodiment, the digital waveform signal may be a sinusoidal wave signal, a square wave signal or a pseudo randomness binary sequence (PRBS) signal. In addition, the controller 11 may further include a PRBS pattern generator and a bit error rate (BER) tester; the BER tester may be a photo detector.

The motherboard 12 includes a test area 121 and a fiber-optics communication component D is disposed on the test area 121. In the embodiment, the fiber-optics communication component D may be a laser package element, such as transmit optical sub-assembly (TOSA). In another embodiment, the test area 121 may further include a slot and the fiber-optics communication component D may be a transceiver; the transceiver can be inserted into the slot for test. In still another embodiment, the fiber-optics communication component D may be a laser diode, a laser package element, a photodiode, a light receiving package element or a light transmitting package element.

The connector 13 is disposed on the motherboard 12. The daughterboard 11 includes a terminal (e.g. gold finger) and the connector 13 includes a socket. The terminal of the daughterboard 11 can be inserted into the socket, such that the daughterboard 11 can be detachably connected to the connector 13.

The fiber-optics communication component test device 1 may further include power connectors P, cable connectors C, power switches S, USB connectors U and various electronic components. The functions of the above elements are already known by those skilled in the art, so will not be described therein.

When performing a test, a tester can fix the fiber-optics communication component D on the test area via a fixture (e.g. probe) and the fiber-optics communication component D can receive the digital waveform signal of the controller 11 via the connector 13. The fiber-optics communication component D can be driven by the digital waveform signal to generate a light signal. Next, the light signal is transmitted to a signal processing system and then the signal processing system processes the light signal by several signal processing steps to generate an input signal. Afterward, the BER tester converts the input signal into an electric signal, and then the controller 111 receives the electric signal and generates a test result according to the electric signal. In the embodiment, the test result may include one or more of bit error rate (BER), voltage amplitude and eye pattern.

Further, as the daughterboard 11 is detachably connected to the connector 13, the tester can replace the daughterboard 11 by another daughterboard 11 so as to satisfy different test requirements. For instance, if the daughterboard 11 is a single-channel test board and the tester needs to execute 4-channel test, the tester can substitute a 4-channel daughterboard 11 for the single-channel daughterboard 11 to execute 4-channel test instead of replacing the test device by another test device.

Moreover, as the fiber-optics communication component test device 1 integrates the daughterboard 11, the motherboard 12 and the connector 13 with each other, so the digital waveform signal generated by the controller 111 of the motherboard 11 can be directly transmitted to the fiber-optics communication component D disposed on the test area 121 of the motherboard 12 via the connector 13 for the fiber-optics communication component D to transmit the light signal. Then, the controller 111 can directly receive the input signal generated by the signal processing system after the signal processing system processes the light signal. Therefore, the fiber-optics communication component test device 1 does not need additional high-frequency connectors, high-frequency cables and test board, which can significantly reduce the cost of multi-channel test.

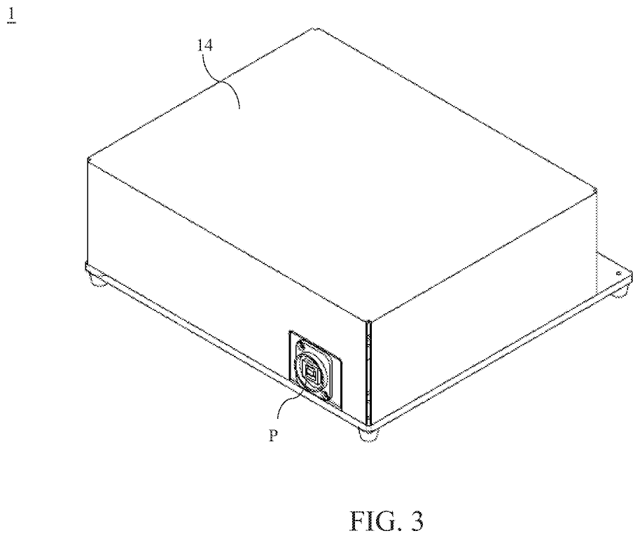

FIG. 3 is a perspective view (with housing) of the fiber-optics communication component test device of the first embodiment. As shown in FIG. 3, the fiber-optics communication component test device 1 further includes a housing 14. At least one portion of the test area 121 is exposed from the housing 14 for the tester to put the fiber-optics communication component D on the test area 121 or replace the fiber-optics communication component D.

The embodiment just exemplifies the disclosure and is not intended to limit the scope of the disclosure. Any equivalent modification and variation according to the spirit of the disclosure is to be also included within the scope of the following claims and their equivalents.

It is worthy to point out that if a tester needs to perform multi-channel test for a fiber-optics communication component by a currently available fiber-optics communication component test device, the tester needs a lot of additional high-frequency connectors and high-frequency cables, which significantly increases the cost of multi-channel test because the high-frequency connectors and high-frequency cables are very expensive. On the contrary, according to one embodiment of the disclosure, the fiber-optics communication component test device integrates a daughterboard, a motherboard and a connector with each other, so the digital waveform signal generated by the controller of the motherboard can be directly transmitted to the fiber-optics communication component disposed on the test area of the motherboard via the connector for the fiber-optics communication component to transmit a light signal. Then, the controller can directly receive the input signal generated by a signal processing system after the signal processing system processes the light signal. Therefore, the fiber-optics communication component test device does not need additional high-frequency connectors, high-frequency cables and test board, which can significantly reduce the cost of multi-channel test.

Besides, the currently available fiber-optics communication component test device has only downward compatibility, but has no upward compatibility, which further increases the cost of multi-channel test. On the contrary, according to one embodiment of the disclosure, the fiber-optics communication component test device integrates the daughterboard, the motherboard and the connector with each other, so the daughterboard can be detachably connected to the connector. Thus, the tester can replace the daughterboard by another daughterboard according to different test requirements, which can further decrease the cost of multi-channel test.

Further, according to one embodiment of the disclosure, the structure of the fiber-optics communication component test device is simple, so can achieve the desire technical effects under this premise of reducing cost, which can significantly increase the commercial value of the test device.

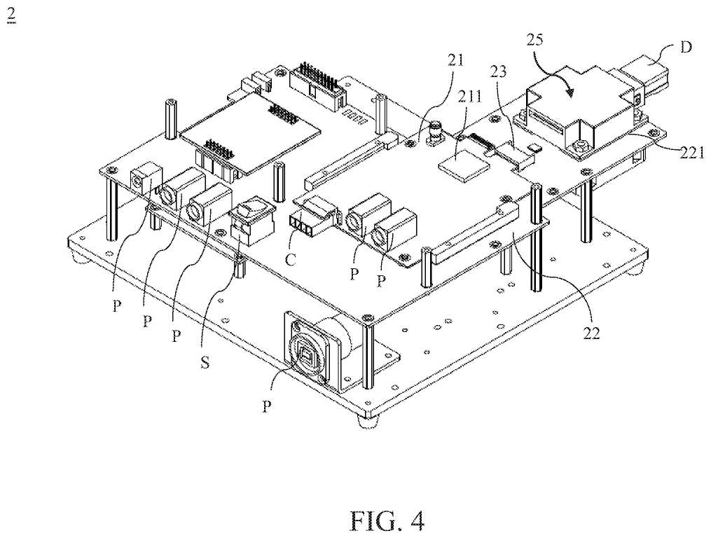

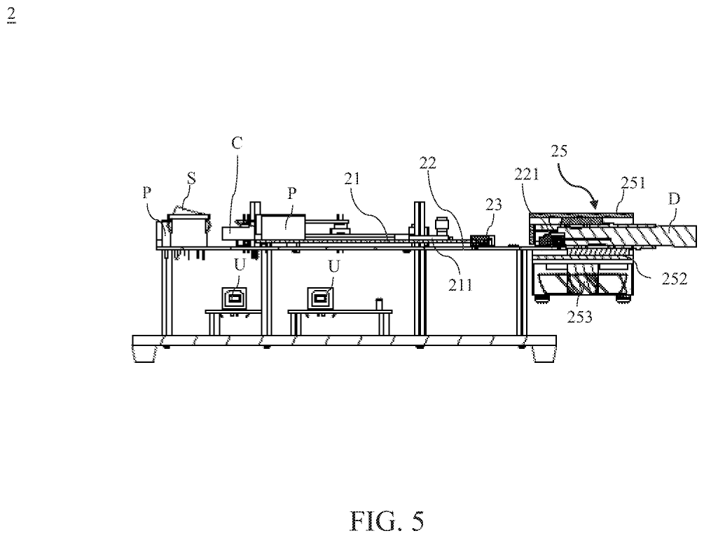

FIG. 4 and FIG. 5 are a perspective view (without housing) and a side view (without housing) of a fiber-optics communication component test device of a second embodiment in accordance with the disclosure respectively. As shown in FIG. 4 and FIG. 5, the fiber-optics communication component test device 2 includes a daughterboard 21, a motherboard 22 and a connector 23 and a thermoelectric cooling chip module 25.

The daughterboard 21 includes a controller 211 and the controller 211 generates a digital waveform signal (or bit signal).

The motherboard 22 includes a test area 221 and a fiber-optics communication component D is disposed on the test area 221. In the embodiment, the fiber-optics communication component D may be a transceiver.

The connector 23 is disposed on the motherboard 22. The daughterboard 21 includes a terminal (e.g. gold finger) and the connector 23 includes a socket. The terminal of the daughterboard 21 can be inserted into the socket, such that the daughterboard 21 can be detachably connected to the connector 23.

The thermoelectric cooling chip module 25 is disposed on the test area 221 and includes an accommodating space. There is a slot inside the accommodating space and the fiber-optics communication component D is inserted into the slot.

When performing a test, a tester can insert the fiber-optics communication component D into the slot inside the thermoelectric cooling chip module 25 and the fiber-optics communication component D can receive the digital waveform signal of the controller 211 via the connector 23. The fiber-optics communication component D can be driven by the digital waveform signal to generate a light signal. Next, the light signal is transmitted to a signal processing system and then the signal processing system processes the light signal by several signal processing steps to generate an input signal. Afterward, the BER tester converts the input signal into an electric signal, and then the controller 211 receives the electric signal and generates a test result according to the electric signal. In the embodiment, the test result may include one or more of bit error rate (BER), voltage amplitude and eye pattern.

Similarly, as the daughterboard 21 is detachably connected to the connector 23, the tester can replace the daughterboard 21 by another daughterboard 21 so as to satisfy different test requirements. Therefore, the fiber-optics communication component test device 2 does not need additional high-frequency connectors, high-frequency cables and test board, which can significantly reduce the cost of multi-channel test.

IF the tester wants to test the fiber-optics communication component D in different temperatures, the tester can change the test temperature by the thermoelectric cooling chip module 25 in order to obtain the test results in different temperatures.

The thermoelectric cooling chip module 25 includes a casing 251, a thermoelectric cooling chip 252 and a cooling fan 253. The thermoelectric cooling chip 252 and the cooling 253 are disposed in the casing 251 and the test space inside the casing 251 is filled with inert gas. The cooling fan 253 can further adjust the test temperatures and the inert gas can effectively prevent from generating condensed water during the tests, so the test results can be more correct.

Via the above structure design, thermoelectric cooling chip module 25 not only can swiftly change the temperature gradient, but also is of low cost, which can effectively the test cost of the fiber-optics communication component D.

In another embodiment, the fiber-optics communication component D may be a laser package element, which can be disposed inside the accommodating space of the thermoelectric cooling chip module 25 and be tested via the similar process.

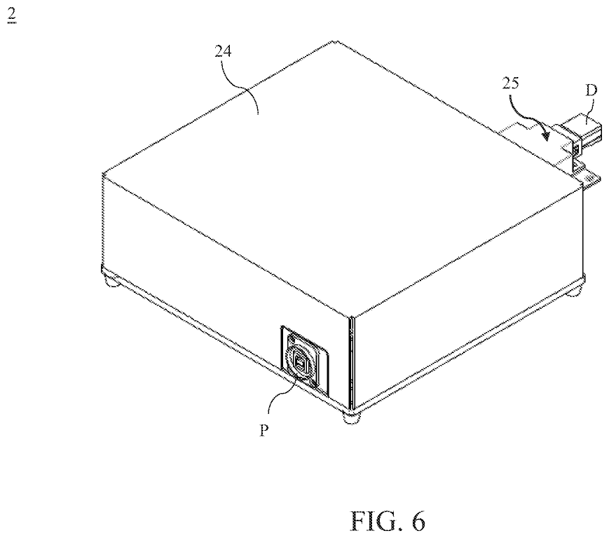

FIG. 6 is a perspective view (with housing) of the fiber-optics communication component test device of the second embodiment. As shown in FIG. 6, the fiber-optics communication component test device 2 further includes a housing 24. At least one portion of the test area 221 is exposed from the housing 24 for the tester to put the fiber-optics communication component D on the test area 221 or replace the fiber-optics communication component D.

The embodiment just exemplifies the disclosure and is not intended to limit the scope of the disclosure. Any equivalent modification and variation according to the spirit of the disclosure is to be also included within the scope of the following claims and their equivalents.

It is worthy to point out that if a tester needs to test a fiber-optics communication component under different temperatures, the tester should change the test temperature via a thermal streamer. The thermal streamer can change the temperature gradient in a short time, but the cost of the thermal streamer is very high, which also increases the test cost of fiber-optics communication components. On the contrary, according to one embodiment of the disclosure, the fiber-optics communication component test device includes a thermoelectric cooling chip module, which not only can swiftly change the temperature gradient, but also is of low cost, which can effectively the test cost of fiber-optics communication components.

In addition, according to one embodiment of the disclosure, the thermoelectric cooling chip module of the fiber-optics communication component test device includes a casing and a thermoelectric cooling chip disposed inside the casing, and the test space of the casing is filled with inert gas, which can effectively prevent from generating condensed water, so the test result can be more correct. As described above, the fiber-optics communication component test device according to the embodiments definitely has an inventive step.

To sum up, according to one embodiment of the disclosure, the fiber-optics communication component test device integrates a daughterboard, a motherboard and a connector with each other, so the digital waveform signal generated by the controller of the motherboard can be directly transmitted to the fiber-optics communication component disposed on the test area of the motherboard via the connector for the fiber-optics communication component to transmit a light signal. Then, the controller can directly receive the input signal generated by a signal processing system after the signal processing system processes the light signal. Therefore, the fiber-optics communication component test device does not need additional high-frequency connectors, high-frequency cables and test board, which can significantly reduce the cost of multi-channel test.

Also, according to one embodiment of the disclosure, the fiber-optics communication component test device integrates the daughterboard, the motherboard and the connector with each other, so the daughterboard can be detachably connected to the connector. Thus, the tester can replace the daughterboard by another daughterboard according to different test requirements, which can further decrease the cost of multi-channel test.

Besides, according to one embodiment of the disclosure, the fiber-optics communication component test device includes a thermoelectric cooling chip module, which not only can swiftly change the temperature gradient, but also is of low cost, which can effectively the test cost of fiber-optics communication components.

Moreover, according to one embodiment of the disclosure, the thermoelectric cooling chip module of the fiber-optics communication component test device includes a casing and a thermoelectric cooling chip disposed inside the casing, and the test space of the casing is filled with inert gas, which can effectively prevent from generating condensed water, so the test result can be more correct.

Further, according to one embodiment of the disclosure, the structure of the fiber-optics communication component test device is simple, so can achieve the desire technical effects under this premise of reducing cost, which can significantly increase the commercial value of the test device.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A fiber-optics communication component test device, comprising:
a daughterboard, comprising a controller configured to generate a digital waveform signal;
a motherboard, comprising a test area;
a connector, disposed on the motherboard and detachably connected to the daughterboard;
wherein a fiber-optics communication component is disposed in the test area and receives the digital waveform signal via the connector to generate a light signal; the light signal is processed by a signal processing system to generate an input signal, and the controller receives the input signal and generates a test result according to the input signal.

2. The fiber-optics communication component test device of claim 1, wherein the daughterboard comprises a terminal and the connector comprises a socket; the terminal of the daughterboard is inserted into the socket, whereby the daughterboard is detachably connected to the connector.

3. The fiber-optics communication component test device of claim 1, further comprising a thermoelectric cooling chip module disposed in the test area, wherein the thermoelectric cooling chip module comprises an accommodating space and the fiber-optics communication component is disposed in the accommodating space.

4. The fiber-optics communication component test device of claim 3, wherein the thermoelectric cooling chip module comprises a casing and a thermoelectric cooling chip; the thermoelectric cooling chip is disposed in the casing and a test space inside the casing is filled with an inert gas.

5. The fiber-optics communication component test device of claim 1, wherein the daughterboard is a single-channel test board or a multi-channel test board.

6. The fiber-optics communication component test device of claim 1, wherein the controller further comprises a pseudo randomness binary sequence pattern generator and a bit error rate tester.

7. The fiber-optics communication component test device of claim 1, wherein the digital waveform signal is a sinusoidal wave signal, a square wave signal or a pseudo randomness binary sequence signal.

8. The fiber-optics communication component test device of claim 1, wherein the test result comprises a bit error rate, a voltage amplitude and an eye pattern.

9. The fiber-optics communication component test device of claim 1, wherein the fiber-optics communication component is a laser diode, a laser package element, a light receiving package element, a light transmitting package element, a photodiode or a transceiver.

10. The fiber-optics communication component test device of claim 1, further comprising a housing and at least one portion of the test area is exposed from the housing.
